(19) United States
(12) Patent Application Publication
(10) Pub. No.: US 2012/0326112 A1
(43) Pub. Date: Dec. 27, 2012

(54) PHASE-CHANGE RANDOM ACCESS MEMORY DEVICE AND METHOD OF MANUFACTURING THE SAME

(76) Inventor: Jang Uk LEE, Ichon-si (KR)

(21) Appl. No.: 13/331,448

(22) Filed: Dec. 20, 2011

(30) Foreign Application Priority Data
Jun. 21, 2011 (KR) 10-2011-0060110

(51) Int. Cl. H01L 47/00; H01L 21/02

(52) U.S. Cl. 257/2; 438/382; 257/E47.001; 257/E21.004

(57) ABSTRACT

A phase-change random access memory (PCRAM) device and a method of manufacturing the same are provided. The PCRAM device includes a semiconductor substrate, a junction word line formed on the semiconductor substrate, an epitaxial word line formed on the junction word line, and a switching device formed on the epitaxial word line.

### CROSS-REFERENCES TO RELATED APPLICATION

The present application claims priority under 35 U.S.C. 119(a) to Korean application number 10-2011-0060110, filed on Jun. 21, 2011 in the Korean Patent Office, which is incorporated by reference in its entirety as if set forth in full.

### BACKGROUND OF THE INVENTION

1. Technical Field

The present invention relates to a semiconductor memory device, and more particularly, to a phase-change random access memory (PCRAM) device and a method of manufacturing the same.

2. Related Art

Generally, PCRAM devices store data using a resistance difference between an amorphous state and a crystalline state due to phase transition of a chalcogen compound. More specifically, the PCRAM devices store data as a logical “0” and a logical “1” using reversible phase transition of a phase-change material layer consisting of germanium (Ge)-antimony (Sb)-tellurium (Te), which is a chalcogen compound, according to a width and length of a pulse applied to the phase change material.

FIG. 1 is a cross-sectional view illustrating a conventional PCRAM device.

Referring to FIG. 1, in the conventional PCRAM device, a junction region 120 serving as a word line is formed on a semiconductor substrate 100 and a switching device 130 is formed on the junction region 120.

A lower electrode 140 is formed on the switching device 130, a phase-change layer 150 is formed on the lower electrode 140 and an upper electrode 160 is formed on the phase-change layer 150. Here, the reference numerals 135, 145, and 155 denote first to third interlayer insulating layers, respectively.

In addition, a word line contact 170 and a metal word line 180 are formed to be connected to a designated number of cell string junction regions 120.

FIG. 2 is a layout diagram of a conventional PCRAM device.

As shown in FIG. 2, in the conventional PCRAM device, a word line contact 170 is formed for every designated number of cell strings (for example, 8) in an extending direction of the metal word line 180.

Here, in the conventional PCRAM device, the metal word line contact 170 is formed to reduce a resistance of the junction region 120. This structure to reduce the resistance of the junction region 120 is formed because the resistance of the junction region 120 is increased as the PCRAM device is highly integrated.

However, since the word line contact 170 is formed between a designated number of the cell strings, the number of the cell strings cannot be increased and a chip size is increased.

### SUMMARY

Exemplary embodiments of the present invention relate to a phase-change random access memory (PCRAM) device capable of increasing the number of cell strings and reducing a chip size and a method of manufacturing the same.

According to one aspect of an exemplary embodiment, a PCRAM device is provided. The PCRAM may include a semiconductor substrate, a junction word line formed on the semiconductor substrate, an epitaxial word line formed on the junction word line, and a switching device formed on the epitaxial word line.

According to another aspect of an exemplary embodiment, a method of manufacturing a PCRAM device is provided. The method may include providing a semiconductor substrate; forming a junction word line on the semiconductor substrate; growing an epitaxial layer on the junction word line to form an epitaxial word line; forming an interlayer insulating layer on the epitaxial word line; etching the interlayer insulating layer to form a contact hole; and forming a switching device within the contact hole.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a cross-sectional view illustrating a conventional phase-change random access memory (PCRAM) device;

FIG. 2 is a layout diagram illustrating a conventional PCRAM device;

FIG. 3 is a cross-sectional view illustrating a PCRAM device according to an exemplary embodiment of the present invention;

FIG. 4 is a layout diagram illustrating a PCRAM device according to an exemplary embodiment of the present invention; and

FIGS. 5A to 5D are diagrams for processes illustrating a method of manufacturing a PCRAM device according to an exemplary embodiment of the present invention.

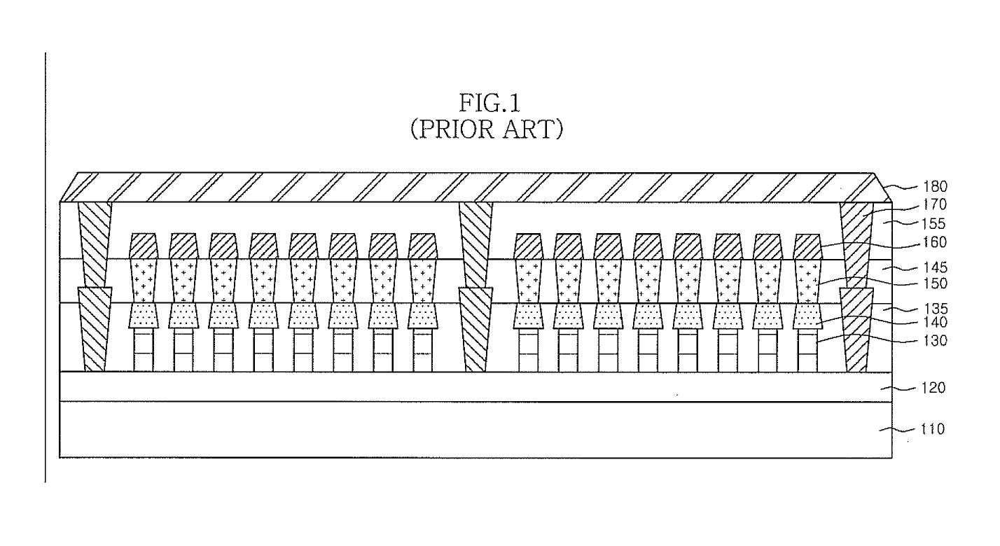

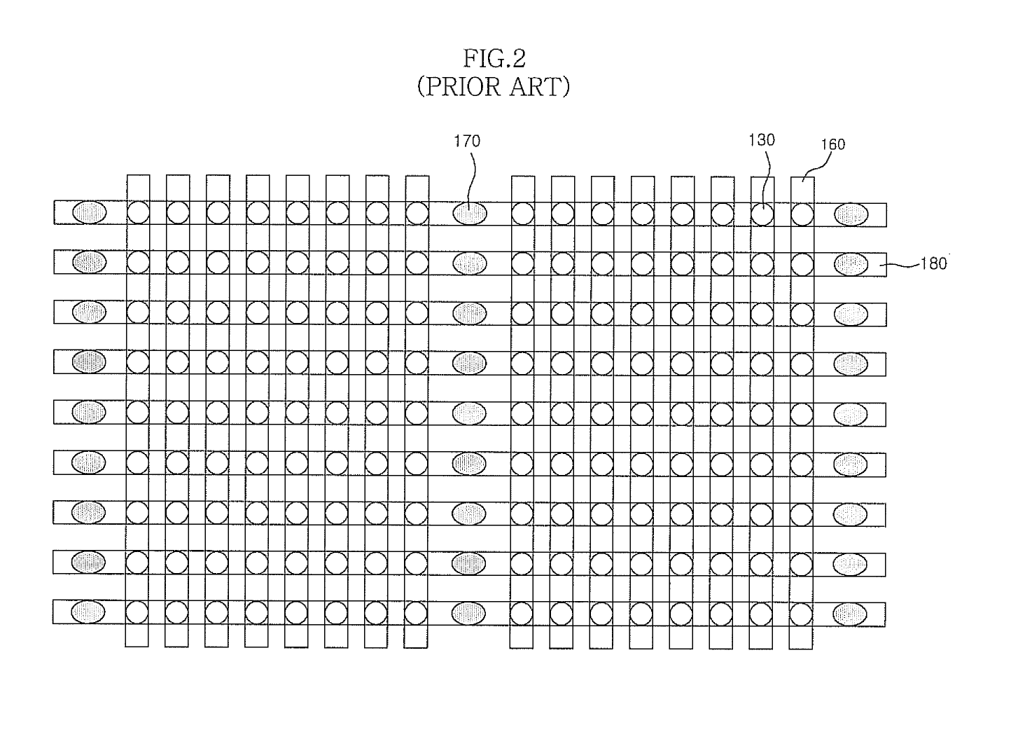

### DESCRIPTION OF EXEMPLARY EMBODIMENT

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

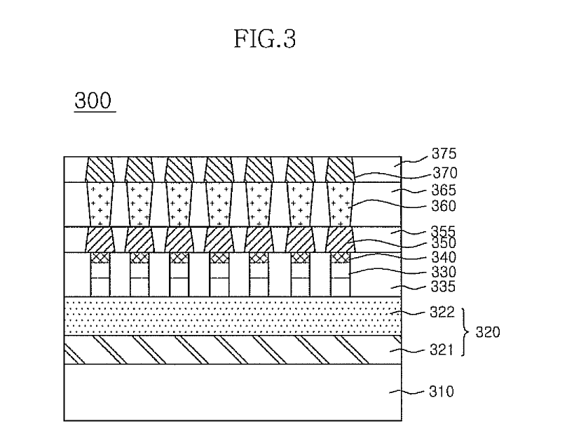

FIG. 3 is a cross-sectional view illustrating a phase-change random access memory (PCRAM) device according to an exemplary embodiment of the present invention.

Referring to FIG. 3, in the PCRAM device 300 of an exemplary embodiment of the present invention, a junction word line 321 containing an n-type impurity is formed on a semiconductor substrate 310. Here, the junction word line 321 is formed using the n-type impurity, but the exemplary embodiment is not limited thereto. The junction word line 321 may be formed using an opposite type impurity or a metal material.

An epitaxial word line 322 is formed on the junction word line 321 to reduce a resistance, which is increased with high integration. The epitaxial word line 322 may be formed by growing a silicon (Si) material on the junction word line 321. Here, a resistance of the PCRAM device 300 according to an exemplary embodiment of the present invention may be controlled according to a height and an impurity concentration of the epitaxial word line 322. Therefore, a word line contact formed to reduce a resistance of the junction word line, as in the related art, may not be formed in the present invention. The epitaxial word line 322 may be formed by the same method as a method of forming a switching diode (in particular, a PN diode) in the related art.

A switching device 330 is formed on the epitaxial word line 322.

A lower electrode 340 is formed on the switching device 330 and a phase-change layer 350 is formed on the lower electrode 340. An upper electrode 360 and a bit line 370 are formed on the phase-change layer 350. The reference numerals 335, 355, 365, and 375 denote first to fourth interlayer insulating layers, respectively.

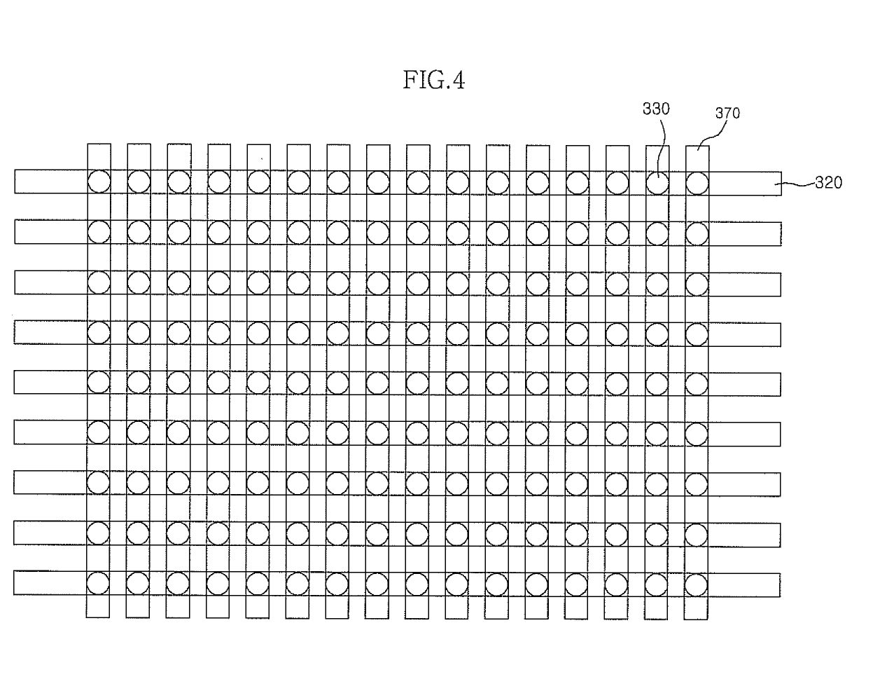

A layout of the PCRAM device 300 according to an exemplary embodiment will be described with reference to FIG. 4.

FIG. 4 is a layout diagram illustrating a PCRAM device according to an exemplary embodiment of the present invention.

Referring to FIG. 4, in the PCRAM device 300 according to an exemplary embodiment of the present invention, the bit line 370 and the word line 320 are formed to be arranged in perpendicular extending directions. In this embodiment, the PCRAM device 300 according to an exemplary embodiment of the present invention may not include a word line contact, which is provided to reduce a resistance of the junction word line 321, as in the related art. Thus, the PCRAM device 300 according to an exemplary embodiment of the present invention is configured to include the junction word line 321 and the epitaxial word line 322 as the word line 320 so that the number of cell strings can be increased and a chip size can be reduced.

Here, the exemplary embodiment of the present invention illustrates that the PCRAM device 300 does not include a word line contact, but the exemplary embodiment is not limited thereto. The word line contact may be formed in the PCRAM device 300. However, a resistance of the junction word line 321 is reduced due to the epitaxial word line 322, and thus, the number of the word line contacts can be reduced as compared with the related art.

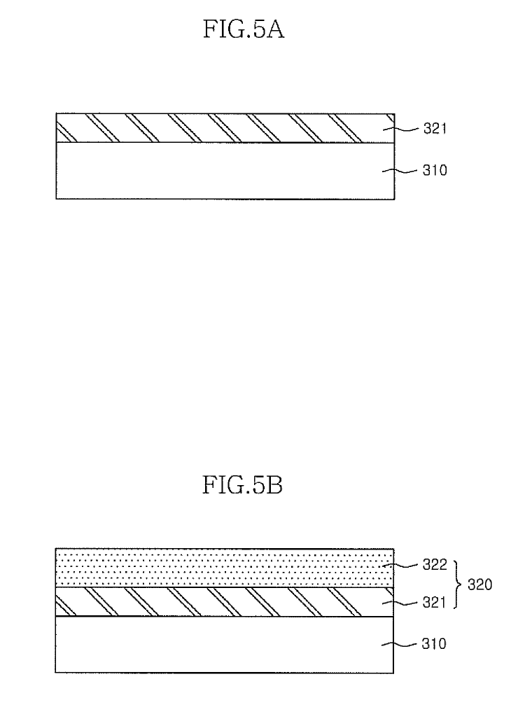

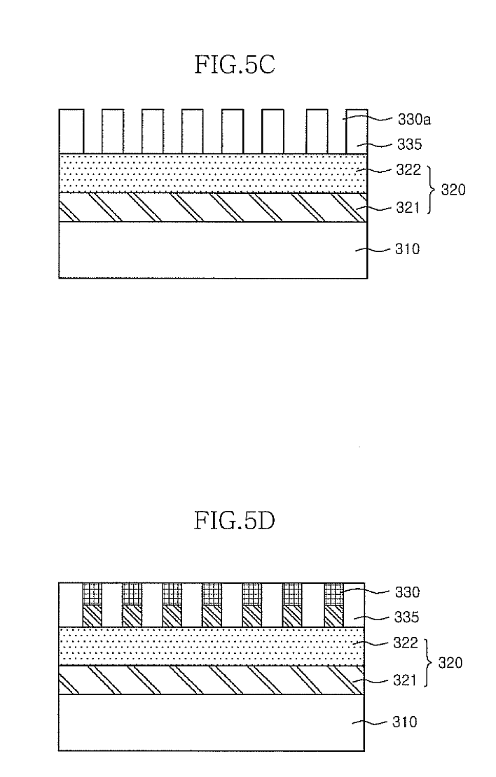

FIGS. 5A to 5D are diagrams for processes sequentially illustrating a method of manufacturing a PCRAM device according to an exemplary embodiment of the present invention.

First, as shown in FIG. 5A, a semiconductor substrate 310 is provided. A junction word line 321 including an n-type impurity (or an opposite type impurity or a metal material) is formed on the semiconductor substrate 310.

As shown in FIG. 5B, an epitaxial layer including a silicon (Si) material is grown on the junction word line 321 to a constant height to reduce a resistance of the junction word line 321, thereby forming an epitaxial word line 322. In this embodiment, the height of the epitaxial word line 322 depends on the resistance of the junction word line 321, or more specifically, an impurity concentration of the junction word line 321.

As shown in FIG. 5C, an interlayer insulating layer 335 is formed on the epitaxial word line 322, and subsequently, a portion of the interlayer insulating layer 335 is etched through a dry etching process to form a contact hole 330a.

As shown in FIG. 5D, after the contact hole 330a is formed, n-type impurities are ion implanted to form an n-type diode region within the contact hole 330a. Subsequently, p-type impurities are ion implanted into an upper portion of the n-type diode region to form a p-type diode region. Therefore, a switching device 330 of a PN diode type is formed. The exemplary embodiment has illustrated that the switching device 330 includes a PN diode, but the exemplary embodiment is not limited thereto.

In addition, the exemplary embodiment has illustrated that after the epitaxial word line 322 is formed, the interlayer insulating layer 335 is formed and subsequently etched to form the contact hole 330a, and the switching device 330 is formed within the contact hole 330a, but the exemplary embodiment is not limited thereto. The switching device 330 may be formed by forming epitaxial layers for the epitaxial word line 322 and the switching device 330 simultaneously and subsequently implanting p-type impurity ions and n-type impurity ions into the epitaxial layer to form the switching device 330.

Subsequently, as shown in FIG. 3, a lower electrode 340, a phase-change layer 350, an upper electrode 360, and a bit line 370 are formed on the switching device 330.

In the PCRAM device 300 according to an exemplary embodiment of the present invention, the epitaxial word line 322 is formed on the junction word line 321 to reduce the resistance of the word line 320 without forming a word line contact.

Thus, the PCRAM device 300 according to an exemplary embodiment of the present invention may not include the word line contact of the related art so that the number of cell strings can be increased and a cell size can be reduced.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A phase-change random access memory (PCRAM) device, comprising:
a semiconductor substrate;
a junction word line formed on the semiconductor substrate;
an epitaxial word line formed on the junction word line; and
a switching device formed on the epitaxial word line.

2. The PCRAM device of claim 1, wherein the junction word line includes a material containing any one of an n-type impurity and a metal material.

3. The PCRAM device of claim 2, wherein the epitaxial word line includes a grown silicon material.

4. The PCRAM device of claim 1, wherein the PCRAM device does not include a word line contact.

5. A method of manufacturing a phase-change random access memory (PCRAM) device, comprising:
providing a semiconductor substrate;
forming a junction word line on the semiconductor substrate;
growing an epitaxial layer on the junction word line to form an epitaxial word line;
forming an interlayer insulating layer on the epitaxial word line;
etching the interlayer insulating layer to form a contact hole; and
forming a switching device within the contact hole.

6. The method of claim 5, wherein the forming the junction word line includes forming the junction word line using any one of an n-type impurity and a metal material.

7. The method of claim 6, wherein the forming the epitaxial word line includes growing a silicon material.

8. The method of claim 7, wherein a height of the epitaxial word line depends on an impurity concentration of the junction word line.
